(19) United States
(12) Patent Application Publication
(10) Pub. No.: US 2025/0370044 A1
(43) Pub. Date: Dec. 4, 2025

(54) APPARATUS AND METHOD TO DETERMINE A CONDITION OF A TACTILE PUSH BUTTON SWITCH USING CAPACITIVE MEASUREMENT

(71) Applicant: Microchip Technology Incorporated, Chandler, AZ (US)

(72) Inventor: Frank Aloe, Brooklin (CA)

(73) Assignee: Microchip Technology Incorporated, Chandler, AZ (US)

(21) Appl. No.: 18/807,955

(22) Filed: Aug. 17, 2024

Related U.S. Application Data
(60) Provisional application No. 63/653,944, filed on May 30, 2024.

(51) Int. Cl. G01R 31/327; G01R 27/26

(52) U.S. Cl. CPC G01R 31/3277; G01R 27/2605

(57) ABSTRACT

An apparatus includes a tactile push button switch including a conductive contact and a conductive switch element, switch press detection circuitry connected to the tactile push button switch to determine an actuation state of the tactile push button switch based on a detected voltage of the tactile push button switch, and switch condition monitoring circuitry to measure a capacitance between the conductive contact and the conductive switch element, determine a condition of the tactile push button switch based on the measured capacitance, and output a switch condition signal indicating the determined condition of the tactile push button switch.

### RELATED APPLICATION

This application claims priority to commonly owned U.S. Provisional Patent Application No. 63/653,944 filed May 30, 2024, the entire contents of which are hereby incorporated by reference for all purposes.

### TECHNICAL FIELD

The present disclosure relates to tactile push button switches (e.g., dome switches and membrane switches), and more particularly to an apparatus and method to determine a condition of a tactile push button switch using capacitive measurement.

### BACKGROUND

A tactile push button switch is a manually operated mechanical switch that provides momentary electrical connection and tactile (haptic) feedback to the user. A tactile push button switch typically includes (a) a conductive contact (e.g., a conductive pad on a circuit board) and (b) a moveable switch element that can be selectively moved between (i) a non-actuated position in which the switch element is spaced apart from conductive contact and (ii) an actuated position in which the switch element contacts the conductive contact to electrically connect the switch element and conductive contact, which may be detected by suitable circuitry.

The moveable switch element may be embodied as a dome, for example a flexible metal “snap dome” element arranged over the conductive contact, or alternatively a polymer switch element including a metal coating or plating arranged over the conductive contacts. A common implementation of a tactile push button switch includes a PCB or flex print with a snap dome or rubber silicon “dome” placed on top.

A tactile push button switch provides a tactile “snap” or other tactile (haptic) feedback to the user. When a user presses a tactile push button switch, the user receives tactile feedback (and in some devices, audible feedback) indicating they have successfully actuated (pressed) the switch. Tactile push button switches are common in various applications, for example medical applications (e.g., IV pumps), keyboards or keypads, aerospace applications (e.g., cockpit control inputs), etc.

With conventional tactile push button switches, a stuck switch can be detected, but other types of failures, degradation or the switch, or other concerning conditions of the switch are typically not detectable. A switch is either open or closed; in a typical arrangement the switch is open when not pressed and closed when pressed. A stuck switch can be detected using a timeout on the button press. However, an open switch presents itself the same as a non-pressed switch, non-connected switch, or even a non-existing connection, such that a failed open switch is typically not detectable.

There is a need for systems and methods for improved monitoring of tactile push button switches.

### SUMMARY

The present disclosure provides systems and methods for monitoring the condition of a tactile push button switch based on capacitance measurements, for example to detect an impending failure of a switch (e.g., due to degradation over time) and/or to detect one or more types of switch faults, e.g., an open switch, disconnected switch, or contaminated switch. For example, some examples include switch condition monitoring circuitry to measure and analyze a capacitance between a conductive contact (e.g., conductive pad on a circuit board) and a moveable conductive switch element (e.g., a metal snap dome or metal-coated/plated polymer element arranged over the conductive contact), in particular in the non-actuated (unpressed) position of moveable switch element. The measured capacitance may be referred to herein as the switch capacitance. The switch condition monitoring circuitry may determine a respective switch condition (e.g., an impending failure of the switch, an open switch fault, a disconnected switch fault, or a contaminated switch fault) based on the measured switch capacitance and/or detected changes in the measured switch capacitance over time.

One aspect provides an apparatus including a tactile push button switch and switch condition monitoring circuitry. The tactile push button switch includes a conductive contact and a conductive switch element, wherein the conductive switch element is physically movable relative to the conductive contact. The switch condition monitoring circuitry to measure a capacitance between the conductive contact and the conductive switch element, determine a condition of the tactile push button switch based on the measured capacitance, and output a switch condition signal indicating the determined condition of the tactile push button switch.

In some examples, the apparatus includes switch press detection circuitry to determine an actuation state of the tactile push button switch based on a detected voltage of the tactile push button switch.

In some examples, one of the conductive contact or the conductive switch element is connected to a reference voltage, and the other one of the conductive contact and the conductive switch element is connected to connected to a signal line, and the conductive switch element is physically movable between (a) a non-actuated position spaced apart from the conductive contact, such that the signal line is electrically disconnected from the reference voltage to define a non-actuated state of the tactile push button switch, and (b) an actuated position in contact with the conductive contact to electrically connect the signal line to the reference voltage to define an actuated state of the tactile push button switch. The switch press detection circuitry to determine the actuation state of the tactile push button switch based on the detected voltage of the tactile push button switch comprises the switch press detection circuitry to determine either the non-actuated state or the actuated state of the tactile push button switch based on a detected voltage on the signal line.

In some examples, the tactile push button switch includes a further conductive contact, one of the conductive contact or the further conductive contact is connected to a reference voltage, and the other one of the conductive contact and the further conductive contact is connected to connected to a signal line. The conductive switch element is physically movable between (a) a non-actuated position in which the conductive switch element is physically spaced apart from at least one of the first and second conductive contacts, such that the first and second conductive contacts are electrically disconnected from each other to define a non-actuated state of the tactile push button switch, and (b) an actuation position in which the conductive switch element physically contacts the first and second conductive contacts to provide an electrical connection between the first and second conductive contacts to define an actuated state of the tactile push button switch. The switch press detection circuitry to determine the actuation state of the tactile push button switch based on the detected voltage of the tactile push button switch comprises the switch press detection circuitry to determine either the non-actuated state or the actuated state of the tactile push button switch based on a detected voltage on the signal line.

In some examples, the conductive switch element comprises a snap dome formed from metal.

In some examples, the conductive switch element comprises a non-conductive element having a conductive element on an interior surface of the non-conductive element.

In some examples, the switch condition monitoring circuitry to measure at least one first capacitance between the conductive contact and the conductive switch element, measure at least one second capacitance between the conductive contact and the conductive switch element, compare the at least one second capacitance to the at least one first capacitance, and determine the condition of the tactile push button switch based at least on the comparison.

In some examples, the switch condition monitoring circuitry includes a capacitive measurement circuit to measure at least one capacitance value of the capacitance between the conductive contact and the conductive switch element, logic instructions stored in non-transitory computer readable media, and a processor to execute the logic instructions to determine the condition of the tactile push button switch based on the at least one measured capacitance value.

In some examples, the switch condition monitoring circuitry includes a capacitive measurement circuit to perform a series of capacitance measurements of the capacitance between the conductive contact and the conductive switch element, logic instructions stored in non-transitory computer readable media, and a processor to execute the logic instructions to (a) determine, based on the series of capacitance measurements, a change in the capacitance between the conductive contact and the conductive switch element over time, and determine the condition of the tactile push button switch based on the determined change in the capacitance between the conductive contact and the conductive switch element over time.

In some examples, determining the condition of the tactile push button switch comprises determining a degradation of the tactile push button switch.

In some examples, determining the condition of the tactile push button switch comprises determining an impending fault.

In some examples, determining the condition of the tactile push button switch comprises determining an open switch fault.

In some examples, determining the condition of the tactile push button switch comprises determining a disconnected switch fault.

One aspect provides an apparatus, including switch condition monitoring circuitry connected to a tactile push button switch including a conductive contact and the conductive switch element, the switch condition monitoring circuitry to measure a capacitance between the conductive contact and the conductive switch element, determine a condition of the tactile push button switch based on the measured capacitance, and output a switch condition signal indicating the determined condition of the tactile push button switch.

In some examples, the switch condition monitoring circuitry to measure at least one first capacitance between the conductive contact and the conductive switch element, measure at least one second capacitance between the conductive contact and the conductive switch element, compare the at least one second capacitance to the at least one first capacitance, and determine the condition of the tactile push button switch based at least on the comparison.

In some examples, the switch condition monitoring circuitry includes capacitance measurement circuitry to measure at least one capacitance value of the capacitance between the conductive contact and the conductive switch element, logic instructions stored in non-transitory computer readable media, and a processor to execute the logic instructions to determine the condition of the tactile push button switch based on the at least one measured capacitance value.

In some examples, the switch condition monitoring circuitry includes a capacitive measurement circuit to perform a series of capacitance measurements of the capacitance between the conductive contact and the conductive switch element, logic instructions stored in non-transitory computer readable media, and a processor to execute the logic instructions to (a) determine, based on the series of capacitance measurements, a change in the capacitance between the conductive contact and the conductive switch element over time, and (b) determine the condition of the tactile push button switch based on the determined change in the capacitance between the conductive contact and the conductive switch element over time.

In some examples, determining the condition of the tactile push button switch comprises determining a degradation of the tactile push button switch.

In some examples, the apparatus includes switch press detection circuitry connected to the tactile push button switch to determine an actuation state of the tactile push button switch based on a detected voltage of the tactile push button switch.

One aspect provide a method, including (a) measuring, by switch condition monitoring circuitry connected to a tactile push button switch, a capacitance between a conductive contact of the tactile push button switch and a moveable conductive switch element of the tactile push button switch, (b) determining, by the switch condition monitoring circuitry, a condition of the tactile push button switch based on the measured capacitance, and (c) outputting, by the switch condition monitoring circuitry, a switch condition signal indicating the determined condition of the tactile push button switch.

In some examples, the method includes (a) measuring, by the switch condition monitoring circuitry, at least one first capacitance between the conductive contact and the conductive switch element, (b) measuring, by the switch condition monitoring circuitry, at least one second capacitance between the conductive contact and the conductive switch element, (c) comparing, by the switch condition monitoring circuitry, the at least one second capacitance to the at least one first capacitance, and (d) determining, by the switch condition monitoring circuitry, the condition of the tactile push button switch based at least on the comparison.

In some examples, the method includes (a) performing, by the switch condition monitoring circuitry, a series of capacitance measurements of the capacitance between the conductive contact and the conductive switch element, (b) determining, by the switch condition monitoring circuitry, based on the series of capacitance measurements, a change in the capacitance between the conductive contact and the conductive switch element over time, and (c) determining, by the switch condition monitoring circuitry, the condition of the tactile push button switch based on the determined change in the capacitance between the conductive contact and the conductive switch element over time.

In some examples, the method includes determining, by switch press detection circuitry connected to the tactile push button switch, an actuation state of the tactile push button switch based on a detected voltage of the tactile push button switch.

### BRIEF DESCRIPTION OF THE DRAWINGS

Example aspects of the present disclosure are described below in conjunction with the figures, in which:

FIG. 1 shows an example apparatus including a tactile push button switch (in particular, a “snap dome” type switch) and switch condition monitoring circuitry to monitor a condition of the tactile push button switch based on capacitance measurements;

FIG. 2 shows an example apparatus including a tactile push button switch (in particular, a “polymer flex” type switch) and switch condition monitoring circuitry to monitor a condition of the tactile push button switch based on capacitance measurements;

FIG. 3 shows an example apparatus including a tactile push button switch, switch condition monitoring circuitry to monitor a switch condition of the tactile push button switch, and switch press detection circuitry to detect an actuation of the tactile push button switch;

FIG. 4 shows another example apparatus including a tactile push button switch, switch condition monitoring circuitry, and switch press detection circuitry;

FIG. 5 shows an example apparatus including an example tactile push button switch including a moveable switch element configured to electrically connect two underlying switch contacts in the actuated position of the switch element;

FIG. 6 shows an example apparatus showing an example implementation of switch condition monitoring circuitry and switch press detection circuitry connected to an example tactile push button switch; and

FIG. 7 shows an example method of monitoring a condition of a tactile push button switch.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

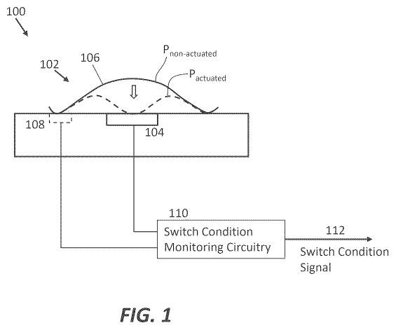

FIG. 1 shows an example apparatus 100 including a tactile push button switch 102 (in particular, a “snap dome” type switch) and switch condition monitoring circuitry 110 to monitor a condition of the tactile push button switch 102 based on capacitance measurements. The tactile push button switch 102 may include a conductive contact 104 and a conductive switch element 106 that is physically movable relative to the conductive contact 104. For example, the conductive switch element 106 may be physically movable, e.g., by a user pressing the conductive switch element 106, between (a) a non-actuated position (indicated at P_{non-actuated}) in which the conductive switch element 106 is spaced apart from the conductive contact 104, defining a non-actuated state of the tactile push button switch 102 and (b) an actuated position (indicated at P_{actuated}) in which the conductive switch element 106 contacts the conductive contact 104, defining an actuated state of the tactile push button switch 102. In this example, the conductive switch element 106 comprises a metal snap dome that can be pressed from the non-actuated position P_{non-actuated} to the actuated position P_{actuated}, and when released, automatically “snaps” back to the non-actuated position P_{non-actuated}.

The conductive switch element 106 may be fixedly connected to an optional switch element contact 108. In some examples, the conductive contact 104 and/or the optional switch element contact 108 may comprise a metal trace or pad on a circuit board.

As discussed below, the apparatus 100 may include switch press detection circuitry to detect a pressing/actuation of the tactile push button switch 102. For example, the conductive contact 104 or the conductive switch element 106 (e.g., via the optional switch element contact 108) may be connected to a reference voltage V_{REF} (e.g., ground or other reference voltage), and the other one of the conductive contact 104 or conductive switch element 106 may be connected to a signal line connected to the switch press detection circuitry. When the switch is pressed/actuated (i.e., wherein the conductive switch element 106 contacts the conductive contact 104), the signal line becomes connected to the reference voltage V_{REF}. The switch press detection circuitry may thus determine whether the switch is actuated based on the voltage on the signal line (e.g., by comparing the voltage on the signal line to a threshold voltage).

As noted above, the apparatus 100 may include switch condition monitoring circuitry 110 to monitor a condition of the tactile push button switch 102 based on capacitance measurements, for example as follows. When the conductive switch element 106 and conductive contact 104 are spaced apart from each other in the non-actuated (unpressed) position P_{non-actuated}, a capacitance (referred to herein as a switch capacitance) is defined between the conductive switch element 106 and conductive contact 104. The switch capacitance is electrically in parallel with the switch defined by the conductive switch element 106 and conductive contact 104. The switch capacitance may vary as a function of the conditions of the tactile push button switch 102, for example as a function of a degradation of the switch 102 over time, or in response to various types of faults or failures of the switch 102.

The switch condition monitoring circuitry 110 may thus monitor the condition of the tactile push button switch 102 by monitoring the switch capacitance, i.e., the capacitance between the conductive switch element 106 and conductive contact 104 in the non-actuated (unpressed) position P_{non-actuated} of the conductive switch element 106. As shown, the switch condition monitoring circuitry 110 may be connected to the conductive contact 104 and to the conductive switch element 106 (e.g., directly or via the optional switch element contact 108).

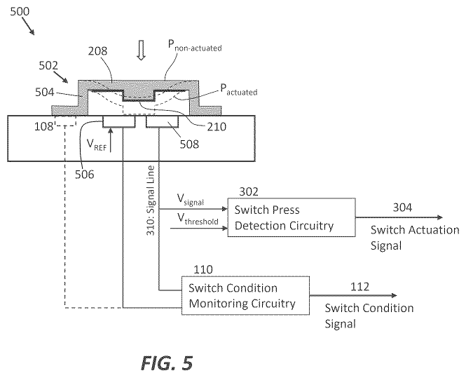

The switch condition monitoring circuitry 110 may include (a) capacitance measurement circuitry to measure the switch capacitance, and (b) circuitry to determine a condition of the tactile push button switch 102 (also referred to herein as a switch condition) based on the measured capacitance, and output a switch condition signal 112 indicating the determined switch condition. The capacitance measurement circuitry may include, for example, an analog-to-digital converter (ADC), and Op-amp, and/or other suitable circuitry. As discussed in detail below with reference to FIG. 5, the circuitry to determine the switch condition and output the switch condition signal 112 may include logic instructions (e.g., embodied in software and/or firmware) stored in memory, and a processor to execute the logic instructions. The switch condition signal 112, which may encode the determined switch condition, may be forwarded to an appropriate device, which may display or otherwise communicate information indicating the determined switch condition to an appropriate person or entity for correction action.

In some examples the switch condition monitoring circuitry 110 may perform capacitance measurements at a defined frequency, for example, 50-100 Hz, and detect changes or trends in the measured capacitance over time. Such changes or trends in the measured capacitance may indicate a respective condition of the tactile push button switch 102, for example a gradual degradation of the switch 102 over time, an impending failure of a switch, or a particular fault of the switch 102, for example an open switch, disconnected switch, or contaminated switch fault.

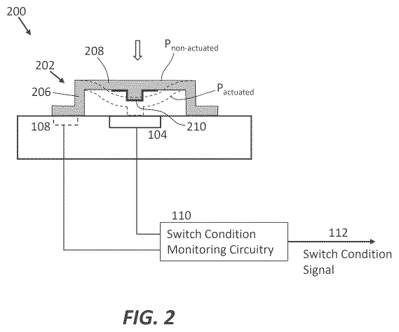

FIG. 2 shows an example apparatus 200 including a tactile push button switch 202 (in particular, a “polymer flex” type switch) and switch condition monitoring circuitry 110 to monitor a condition of the tactile push button switch 102 based on capacitance measurements. The example apparatus 200 may be similar to the example apparatus 100 discussed above; however, instead of the “metal snap dome” type conductive switch element 106 of tactile push button switch 102, the tactile push button switch 202 of apparatus 200 may utilize a conductive switch element 206 comprising a polymer element 208 (e.g., formed from silicon or rubber) with a conductive element 210 (e.g., a metal layer, film, or coating) on an interior side of the polymer element 208 facing the conductive contact 104. Like the conductive switch element 106 discussed above, the conductive switch element 206 may be physically moved (pressed) from (a) a non-actuated position P_{non-actuated} in which the conductive switch element 206 (in particular the conductive element 210) is spaced apart from the conductive contact 104, defining a non-actuated state of the tactile push button switch 202 and (b) an actuated position P_{actuated} in which the conductive switch element 206 (in particular the conductive element 210) contacts the conductive contact 104, defining an actuated state of the tactile push button switch 202. Like the conductive switch element 106 discussed above, the conductive switch element 206 may automatically return (spring back) to the non-actuated position P_{non-actuated} when released by the user.

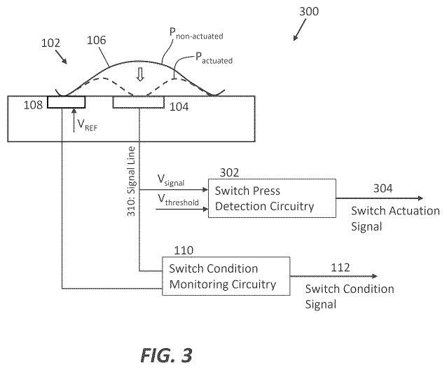

FIG. 3 shows an example apparatus 300 including the example tactile push button switch 102, switch condition monitoring circuitry 110 to monitor a switch condition of the tactile push button switch 102, and switch press detection circuitry 302 to detect an actuation of the tactile push button switch 102. In this example, the conductive switch element 106 is connected to a reference voltage V_{REF} (e.g., via switch element contact 108) and the conductive contact 104 is connected to a signal line 310.

The signal line 310 is connected to switch press detection circuitry 302 to determine the actuation state of the tactile push button switch 102 based on a detected voltage V_{signal} on the signal line 310 and output a switch actuation signal 304 indicating the determined actuation state. For example, the switch press detection circuitry 302 may include circuitry to determine whether the tactile push button switch 102 is in the non-actuated state (in which the conductive switch element 106 is spaced apart from the conductive contact 104) or the actuated state (in which the conductive switch element 106 contacts the conductive contact 104), e.g., using a comparator to compare the signal line voltage V_{signal} to a threshold voltage V_{threshold}, e.g., as discussed below with reference to FIG. 5. In some examples the signal line may be floating and thus connected to a pull-up resistor to provide a stable impedance in the non-actuated state of the switch 102.

The switch condition monitoring circuitry 110 may be connected between the conductive contact 104 and the conductive switch element 106 (in this example, via the switch element contact 108). As discussed above, the switch condition monitoring circuitry 110 may perform a series of switch capacitance measurements (e.g., at a defined frequency) in the non-actuated (unpressed) position P_{non-actuated} of the conductive switch element 106, to monitor the condition of the tactile push button switch 102, analyze the measured capacitance over time to detect various conditions of the switch 102, and output switch condition signals 112 indicating detected switch conditions, e.g., as discussed above regarding FIG. 1.

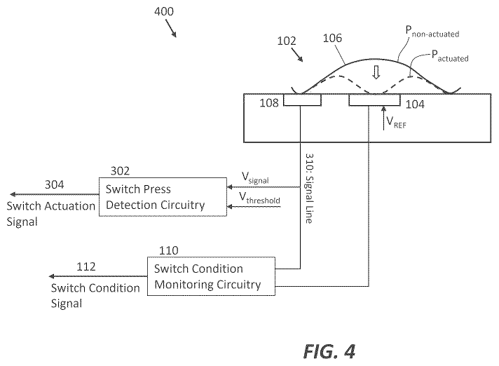

FIG. 4 shows an example apparatus 400 including the example tactile push button switch 102, switch condition monitoring circuitry 110, and switch press detection circuitry 302. The example apparatus 400 may be similar to the example apparatus 300 shown in FIG. 3; however, in apparatus 400 the conductive switch element 106 is connected to the signal line 310 (e.g., via switch element contact 108), and the conductive contact 104 is connected to the reference voltage V_{REF}. Apparatus 400 may otherwise operate similar to apparatus 300 discussed above.

Although the apparatus 300 and apparatus 400 are illustrated (in FIGS. 3 and 4) with the example tactile push button switch 102, it should be understood the example tactile push button switch 202 may alternatively be used in apparatus 300 and apparatus 400.

FIG. 5 shows an example apparatus 500 including an example tactile push button switch 502, switch condition monitoring circuitry 110, and switch press detection circuitry 302. The example apparatus 500 may be similar to any of the example apparatuses 100-400 discussed above, except the configuration of the tactile push button switch 502. As shown, the tactile push button switch 502 includes a conductive switch element 504 arranged of a pair of spaced-apart conductive contacts 506 and 508, as opposed to the single conductive contact 104 of the example apparatuses 100-400 discussed above. As shown, the conductive contact 506 is connected to a reference voltage V_{REF} (e.g., ground or other reference voltage), and the other conductive contact 508 is connected to the signal line 310. The pair of conductive contacts 506 and 508 may also be referred to herein as a conductive contact and a further conductive contact.

In the illustrated example, the conductive switch element 504 is similar to conductive switch element 206 shown in FIG. 2, including the polymer element 208 with the conductive element 210 (e.g., a metal layer, film, or coating) on an interior side of the polymer element 208 facing the conductive contacts 506 and 508. However, it should be understood the conductive switch element 504 may alternatively comprise a metal snap dome (such as the example tactile push button switch 102 discussed above) or other type of conductive switch element.

In the non-actuated position P_{non-actuated} of the conductive switch element 504, the conductive switch element 504 (in particular, the conductive element 210) is spaced apart from the pair of conductive contacts 506 and 508, and the conductive contacts 506 and 508 remain electrically disconnected from each other, defining the non-actuated state of the switch 502. When the conductive switch element 504 is actuated (pressed) to the actuated position P_{actuated}, the conductive switch element 504 (in particular, the conductive element 210) contacts both conductive contacts 506 and 508 to form an electrical connection between the conductive contacts 506 and 508, thereby defining the actuated state of the switch 502.

Similar to the example apparatuses 300 and 400 discussed above, apparatus 500 may include switch press detection circuitry 302 connected to the signal line 310 to determine the actuation state of the tactile push button switch 102 based on a detected voltage V_{signal} on the signal line 310. Apparatus 500 may also include switch condition monitoring circuitry 110 to measure the capacitance between the conductive contacts 506 and 508, and monitor a condition of the tactile push button switch 102 based on such capacitance measurements, e.g., as described above.

In an alternative example, the switch condition monitoring circuitry 110 may alternatively be conductively connected between (a) one of the contacts 506, 508 and (b) the conductive switch element 504, for example via an optional switch element contact 108.

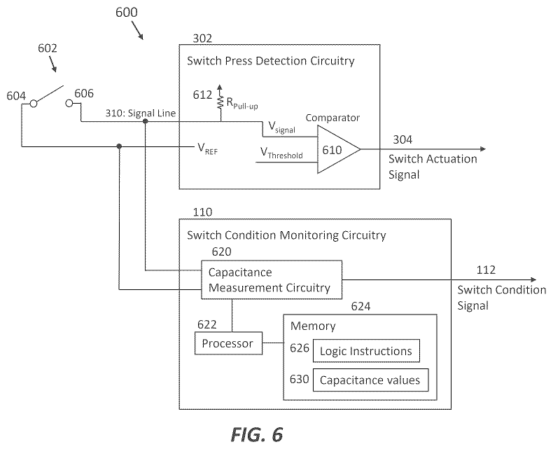

FIG. 6 shows an example apparatus 600 including a tactile push button switch 602 including switch contacts 604 and 606, switch condition monitoring circuitry 110, and switch press detection circuitry 302. The tactile push button switch 602 may, for example, correspond with either of the example tactile push button switches 102 or 202 discussed above, wherein the switch contacts 604 and 606 may correspond with the conductive switch element 106 and conductive contact 104, or vice versa.

As shown, the switch press detection circuitry 302 may include a comparator 610 to compare a voltage V_{signal} on the signal line 310 with a threshold voltage V_{threshold}, and output a binary (low or high) switch actuation signal 304 indicating the actuation state of the tactile push button switch 602. For example, in the non-actuated state of the switch 602, the signal line voltage V_{signal} is greater than or equal to the threshold voltage V_{threshold}, and the comparator 610 outputs a low switch actuation signal 304, and when the switch 602 is actuated, the signal line voltage V_{signal} is less than the threshold voltage V_{threshold}, and the comparator 610 outputs a high switch actuation signal 304. As shown, the signal line 310 may be connected to a pull-up resistor 612 to provide a stable impedance in the non-actuated state of the switch 602.

The switch condition monitoring circuitry 110 may include capacitance measurement circuitry 620, a processor 622, and a memory 624 storing logic instructions 626, e.g., embodied in software and/or firmware executable by the processor 622. The capacitance measurement circuitry 620 may include circuitry to measure a capacitance (switch capacitance) between the switch contacts 604 and 606. For example, the capacitance measurement circuitry 620 may include an analog-to-digital converter (ADC), and Op-amp, and/or other suitable circuitry, which may perform a charge transfer measurement to measure a charge transfer proportional to capacitance.

The processor 622 may comprise a microcontroller, microprocessor, FPGA, or other processor. Memory 624 may comprise EEPROM, Flash memory, or any other type of memory. The processor 622 may store switch capacitance values 630 measured by capacitance measurement circuitry 620 in memory 624, for example to monitor the switch capacitance over time.

The logic instructions 626 may be executable by the processor 622 to monitor a condition of the switch 602 over time, e.g., based on a series of switch capacitance measurements by capacitance measurement circuitry 620. In some examples, logic instructions 626 may be executable to determine multiple different types of faults of the switch 602, for example including (a) a degradation or impending failure of the switch 602, (b) an open switch, (c) a disconnected switch, (d) a loose contact, and/or (e) a contaminated switch. In some examples, logic instructions 626 may be executable to identify the existence of particular type of fault (from multiple different types of faults), for example based on the behavior of the measured switch capacitance over time.

For example, the capacitance measurement circuitry 620 may take a series of switch capacitance measurements over time, and logic instructions 626 may be executed to determine a degradation of the switch 602 based on changes in the switch capacitance over time. For example, a first switch capacitance measurement or first set of switch capacitance measurements may define a baseline value, against which subsequent switch capacitance measurements may be compared over time. Switch capacitance measurements may be stored as capacitance values 630. The switch condition monitoring circuitry 110 (e.g., by processor 622 executing respective logic instructions 626) may determine a degradation of the switch 602 by determining a gradual decrease of the switch capacitance over time, and may detect an “impending failure” condition of the switch 602 if the switch capacitance gradually decreases and falls beyond a defined threshold, and generate an “impending fault” notification.

As another example, logic instructions 626 may detect an open switch fault (e.g., resulting from a broken switch element 106 or physical disconnection of a switch contact 604 or 606 from the switch condition monitoring circuitry 110) by determining a large rapid decrease in the monitored switch capacitance. For example, an open switch may be detected if the switch capacitance decreases by more than a defined amount (e.g., a threshold magnitude of decrease) within a defined (short) time period, for example similar to a step function.

As another example, logic instructions 626 may detect a disconnected switch fault (e.g., resulting from the switch 602 being unplugged or otherwise disconnected from a power source) by determining a large rapid decrease in switch capacitance to zero or below a defined low threshold value. For example, a disconnected switch may be detected if the switch capacitance decreases by more than a defined amount (e.g., a threshold magnitude of decrease) within a defined (short) time period and falls below a defined disconnected switch threshold value (e.g., zero or very low threshold value). In some examples, logic instructions 626 may distinguish an open switch from a disconnected switch based on the switch capacitance value after the sudden decrease, e.g., wherein the switch capacitance for a disconnected switch falls below the disconnected switch threshold value (e.g., zero or very low threshold value), while an open switch may fall to a low value but above the disconnected switch threshold value.

As another example, logic instructions 626 may detect a loose connection in the switch 602 (e.g., a loose connection to switch contact 604 or 606) by detecting a series of rapid increases and decreases in the monitored switch capacitance, for example based on defined threshold values for the magnitude of increase/decrease and time periods in which such increases/decreases occur.

As another example, logic instructions 626 may detect a contaminated switch by detecting an increase in the monitored switch capacitance, for example due to the introduction of oil or other dielectric into the switch element 106 (e.g., inside a snap dome).

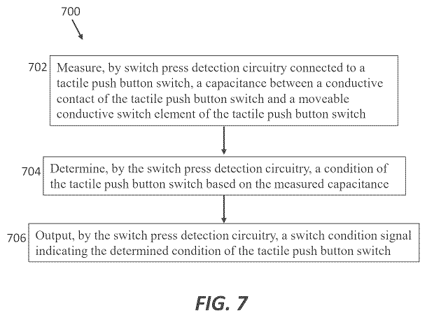

FIG. 7 shows an example method 700 of monitoring a condition of a tactile push button switch. Method 700 may be implemented by any of the example apparatuses 100-600 discussed above. At 702, switch condition monitoring circuitry connected to a tactile push button switch measured a capacitance between a conductive contact of the tactile push button switch and a moveable conductive switch element of the tactile push button switch. At 704, the switch condition monitoring circuitry determines a condition of the tactile push button switch based on the measured capacitance. At 706, the switch condition monitoring circuitry outputs a switch condition signal indicating the determined condition of the tactile push button switch.

Although example embodiments have been described above, other variations and embodiments may be made from this disclosure without departing from the spirit and scope of these embodiments.

1. An apparatus, comprising:
a tactile push button switch including a conductive contact and a conductive switch element, wherein the conductive switch element is physically movable relative to the conductive contact;
switch condition monitoring circuitry to:
measure a capacitance between the conductive contact and the conductive switch element;
determine a condition of the tactile push button switch based on the measured capacitance; and
output a switch condition signal indicating the determined condition of the tactile push button switch.

2. The apparatus of claim 1, comprising switch press detection circuitry to determine an actuation state of the tactile push button switch based on a detected voltage of the tactile push button switch.

3. The apparatus of claim 2, wherein:
one of the conductive contact or the conductive switch element is connected to a reference voltage, and the other one of the conductive contact and the conductive switch element is connected to connected to a signal line;
the conductive switch element is physically movable between:
(a) a non-actuated position spaced apart from the conductive contact, such that the signal line is electrically disconnected from the reference voltage to define a non-actuated state of the tactile push button switch; and
(b) an actuated position in contact with the conductive contact to electrically connect the signal line to the reference voltage to define an actuated state of the tactile push button switch; and
the switch press detection circuitry to determine the actuation state of the tactile push button switch based on the detected voltage of the tactile push button switch comprises the switch press detection circuitry to determine either the non-actuated state or the actuated state of the tactile push button switch based on a detected voltage on the signal line.

4. The apparatus of claim 2, wherein:
the tactile push button switch includes a further conductive contact;
one of the conductive contact or the further conductive contact is connected to a reference voltage, and the other one of the conductive contact and the further conductive contact is connected to connected to a signal line;
the conductive switch element is physically movable between:
(a) a non-actuated position in which the conductive switch element is physically spaced apart from at least one of the first and second conductive contacts, such that the first and second conductive contacts are electrically disconnected from each other to define a non-actuated state of the tactile push button switch; and
(b) an actuation position in which the conductive switch element physically contacts the first and second conductive contacts to provide an electrical connection between the first and second conductive contacts to define an actuated state of the tactile push button switch; and
the switch press detection circuitry to determine the actuation state of the tactile push button switch based on the detected voltage of the tactile push button switch comprises the switch press detection circuitry to determine either the non-actuated state or the actuated state of the tactile push button switch based on a detected voltage on the signal line.

5. The apparatus of claim 1, wherein the conductive switch element comprises a snap dome formed from metal.

6. The apparatus of claim 1, wherein the conductive switch element comprises a non-conductive element having a conductive element on an interior surface of the non-conductive element.

7. The apparatus of claim 1, wherein the switch condition monitoring circuitry to:
measure at least one first capacitance between the conductive contact and the conductive switch element;
measure at least one second capacitance between the conductive contact and the conductive switch element;
compare the at least one second capacitance to the at least one first capacitance; and
determine the condition of the tactile push button switch based at least on the comparison.

8. The apparatus of claim 1, wherein the switch condition monitoring circuitry comprises:
a capacitive measurement circuit to measure at least one capacitance value of the capacitance between the conductive contact and the conductive switch element;
logic instructions stored in non-transitory computer readable media; and
a processor to execute the logic instructions to determine the condition of the tactile push button switch based on the at least one measured capacitance value.

9. The apparatus of claim 1, wherein the switch condition monitoring circuitry comprises:
a capacitive measurement circuit to perform a series of capacitance measurements of the capacitance between the conductive contact and the conductive switch element;
logic instructions stored in non-transitory computer readable media; and
a processor to execute the logic instructions to:
determine, based on the series of capacitance measurements, a change in the capacitance between the conductive contact and the conductive switch element over time; and
determine the condition of the tactile push button switch based on the determined change in the capacitance between the conductive contact and the conductive switch element over time.

10. The apparatus of claim 1, wherein determining the condition of the tactile push button switch comprises determining a degradation of the tactile push button switch.

11. The apparatus of claim 1, wherein determining the condition of the tactile push button switch comprises determining an impending fault.

12. The apparatus of claim 1, wherein determining the condition of the tactile push button switch comprises determining an open switch fault.

13. The apparatus of claim 1, wherein determining the condition of the tactile push button switch comprises determining a disconnected switch fault.

14. An apparatus, comprising:
switch condition monitoring circuitry connected to a tactile push button switch including a conductive contact and the conductive switch element, the switch condition monitoring circuitry to:
measure a capacitance between the conductive contact and the conductive switch element;
determine a condition of the tactile push button switch based on the measured capacitance; and
output a switch condition signal indicating the determined condition of the tactile push button switch.

15. The apparatus of claim 14, wherein the switch condition monitoring circuitry to:
measure at least one first capacitance between the conductive contact and the conductive switch element;
measure at least one second capacitance between the conductive contact and the conductive switch element;
compare the at least one second capacitance to the at least one first capacitance; and
determine the condition of the tactile push button switch based at least on the comparison.

16. The apparatus of claim 14, wherein the switch condition monitoring circuitry comprises:
capacitance measurement circuitry to measure at least one capacitance value of the capacitance between the conductive contact and the conductive switch element;
logic instructions stored in non-transitory computer readable media; and
a processor to execute the logic instructions to determine the condition of the tactile push button switch based on the at least one measured capacitance value.

17. The apparatus of claim 14, wherein the switch condition monitoring circuitry comprises:
a capacitive measurement circuit to perform a series of capacitance measurements of the capacitance between the conductive contact and the conductive switch element;
logic instructions stored in non-transitory computer readable media; and
a processor to execute the logic instructions to:
determine, based on the series of capacitance measurements, a change in the capacitance between the conductive contact and the conductive switch element over time; and
determine the condition of the tactile push button switch based on the determined change in the capacitance between the conductive contact and the conductive switch element over time.

18. The apparatus of claim 17, wherein determining the condition of the tactile push button switch comprises determining a degradation of the tactile push button switch.

19. The apparatus of claim 14, comprising switch press detection circuitry connected to the tactile push button switch to determine an actuation state of the tactile push button switch based on a detected voltage of the tactile push button switch.

20. A method, comprising:
measuring, by switch condition monitoring circuitry connected to a tactile push button switch, a capacitance between a conductive contact of the tactile push button switch and a moveable conductive switch element of the tactile push button switch;
determining, by the switch condition monitoring circuitry, a condition of the tactile push button switch based on the measured capacitance; and
outputting, by the switch condition monitoring circuitry, a switch condition signal indicating the determined condition of the tactile push button switch.

21. The method of claim 20, comprising:
measuring, by the switch condition monitoring circuitry, at least one first capacitance between the conductive contact and the conductive switch element;
measuring, by the switch condition monitoring circuitry, at least one second capacitance between the conductive contact and the conductive switch element;
comparing, by the switch condition monitoring circuitry, the at least one second capacitance to the at least one first capacitance; and
determining, by the switch condition monitoring circuitry, the condition of the tactile push button switch based at least on the comparison.

22. The method of claim 20, comprising:
performing, by the switch condition monitoring circuitry, a series of capacitance measurements of the capacitance between the conductive contact and the conductive switch element;
determining, by the switch condition monitoring circuitry, based on the series of capacitance measurements, a change in the capacitance between the conductive contact and the conductive switch element over time; and
determining, by the switch condition monitoring circuitry, the condition of the tactile push button switch based on the determined change in the capacitance between the conductive contact and the conductive switch element over time.

23. The method of claim 20, comprising determining, by switch press detection circuitry connected to the tactile push button switch, an actuation state of the tactile push button switch based on a detected voltage of the tactile push button switch.
